(19) United States
(12) Patent Application Publication
(10) Pub. No.: US 2007/0292339 A1
(43) Pub. Date: Dec. 20, 2007

(54) Iron Oxide Whisker of High Aspect Ratio, Titanium Oxide Whisker of High Aspect Ratio, Structure Containing These and Process for Producing Them

(75) Inventors: Kenji Kubomura, Ishikawa (JP); Morihiro Okada, Chiba (JP); Ikuo Jutsuhara, Chiba (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: KANAZAWA R AND D LTD., Kanazawa-shi, Ishikawa (JP)

(21) Appl. No.: 10/594,238

(22) PCT Filed: Mar. 18, 2005
(86) PCT No.: PCT/JP05/04928

§ 371 Date: Jul. 2, 2007

(30) Foreign Application Priority Data
Mar. 23, 2004 (JP) 2004-085762

(51) Int. Cl. C30B 29/62; C01G 23/04; C01G 49/02

(52) U.S. Cl. 423/608; 420/417; 420/8; 423/633

(57) ABSTRACT

An iron oxide whisker of high aspect ratio or titanium oxide whisker of high aspect ratio that is useful as a magnetic material for magnetic recording, a part of micromachine, etc.; and a structure having such a whisker erected on a basal plate that is useful as a catalyst, etc. There is provided an iron oxide whisker of 5 nm to 2 μm diameter and ≧20 aspect ratio wherein the content of non-iron metal atoms is ≦10 at %, and provided a titanium oxide whisker of 5 nm to 20 μm diameter and ≧5 aspect ratio wherein the content of non-titanium metal atoms is ≦10 at %. Further, there is provided a structure, such as a basal plate having these whiskers densely erected thereon. These whiskers excel in magnetic properties, etc., and the structures having these erected exert excellent characteristics, such as large contact area as a catalyst and freedom from clogging, and hence are useful. In the production of these oxide whiskers, an iron or titanium material is brought into contact with an oxidative atmosphere so as to react the surface iron or titanium atoms with oxygen brought into contact therewith at high temperature, thereby attaining growth as oxide whiskers.

### BACKGROUND OF THE INVENTION

The present invention relates to iron oxide whisker of high aspect ratio, titanium oxide of high aspect ratio, structure containing these and process for producing them.

These whiskers excel in magnetic properties, etc and the structures having these erected exert excellent characteristics, such as large contact area as a catalyst and freedom from clogging, and hence are useful.

As effective magnetic storage media, magnetic particles are required to maintain a high magnetic coercivity. The high coercivity is obtained with needle like particles of high density which are free from being fused between particles and voids on the surface or inside of the particles. It is a common practice that whiskers or particles of magnetite are synthesized through aqueous precipitation (hydrogenreduction of ferrous chloride,) or chemical reduction of αFe₂O₃.(JPH6-64927A) (JPH 7-242425 A) (JPH 8-8104 A). The particles and whiskers synthesized by these methods include dendrites, fusiform or spherical particles which are detrimental to a higher magnetic coercivity. The production of high aspect ratio whiskers with less dendrites is highly desirable because aspect ratios of those obtained are aspect ratios up to 20 (JPS 47-2595 B)or up to 16 (JPH 8-8104 A).

Some whiskers have unusual strength approaching theoretical strength of perfect crystals when they are nearly perfect crystals and are free of dislocations. By exploiting this strength, many products using whiskers are developed and also are being investigate for development. For an example, Goethite whiskers (JP2001-240500 A) of aspect ratios up to 260 are investigated for use in a micro-machine. However, due to the production method limitation the goethite whiskers contain significant amount of substitution metal atoms such as cobalt, nickel, chromium and titanium atoms (in the case for cobalt; between 15 atom % and 35 atom %) and as result, their strength is much smaller than that of the theoretical value of perfect crystal. For the use in a micro-machine, the desired iron oxide whiskers are straight single crystals with high aspect ratios. The whiskers in the present invention include said straight single crystals and further include whiskers having cross sections in the shape of single walled tube, multi walled tube, spiral wire and onion texture polycrystalline, radial texture polycrystalline as those of carbon fibers, and polycrystalline whiskers with multi steps. Further, the whiskers include high aspect ratio whiskers in the form of spiral wire, felt of tangled whiskers, zigzag wire and whiskers grown many different directions from one point.

With the understanding of the effect of carbon dioxide on the global warming, that the Earth as a whole is rapidly getting warmer and that atmospheric carbon is increasing at dramatic rates, the development of clean energy sources and the reduction or removal of carbon dioxides have become urgent concerns. For example, in the separation process of carbon dioxide by MEA absorption, the renewal use of recovered carbon as a resource is limited. For the reduction of carbon dioxide gas, oxygen deficient magnetite is investigated as a reduction catalyst in the form of particulate (Tamaura, New Material: Oxygen Defect Magnetite, Functional Materials, December, 1990, pp 44-49)), (JPH 3-245845 A), (JPH 3-285829 A). Though magnetite particles work as effective catalysts for the reduction of carbon dioxide gas, the particles agglomerate and clog the carbon dioxide gas passage, impairing the catalysis performance. To avoid the clogging, fibers coated with oxygen deficient magnetite particles were investigated (JPH7-41322 A), in which the fibers of a length shorter than 3 μm tend to break and the coating of magnetite particles on fibers of length longer than 50 mm is difficult. When compared to the particle magnetite, the coated fibers decrease the amount of magnetite catalyst per unit volume, thereby limiting the carbon dioxide removal efficiency.
Patent Document 1: JPH6-64927 A.
Patent Document 2: JPH7-242425 A.
Patent Document 3: JPH8-8104 A.
Patent Document 4: JPS 47-25959 B.
Patent Document 5: JP 2001-240500 A.
Patent Document 6: JPH3-245845 A.
Patent Document 7: JPH3-285829 A.
Patent Document 8: JPH7-41322 A.
Non-patent Document 1: Tamaura, New Material: Oxygen Defect Magnetite, Functional Materials, December, 1990, pp 44-49.

Titanium oxides have a great potential as photocatalyst for the decomposition of contaminants, deodorization and antimicrobial activities. The problem using TiO₂ film or TiO₂ particles coated film is the limited surface area for catalysis activities in addition to the problem of the degradation of the catalysis effectiveness due to the accumulation of contaminants on the surface. The surface area can be increased by the use of dispersed particles or whiskers, but the particles form clusters and clog the contaminants passage way, thus reducing the catalysis effectiveness. To prevent the particles from forming clusters and to remove contaminants smeared on the particles, the cavitation was used, which required the reduced density of whiskers or particles resulting in the low overall catalysis effectiveness. There are several stable phases of titanium oxide and TiO has catalytic characters in addition to having high conductivity, high strength and, high melting temperature (JP 2001-199796 A). The TiO₂ group is composed of rutile, anatase, and brookite, and anatase has photocatalytic and hydrophilic properties.

The preferred titanium oxide whisker is single crystal and straight with a high aspect ratio. Further, the whiskers in the present invention include whiskers having cross sections in the shape of single walled tube, multi walled tube, spiral wire and onion texture polycrystalline, radial texture polycrystalline as those of carbon fibers, and polycrystalline whiskers with multi steps. Further, the whiskers include high aspect ratio whiskers in the form of spiral wire, felt of tangled whiskers and zigzag wire and whiskers grown many different directions from one point.
Patent Document 9: JP 2001-199796 A.
Patent Document 10: JP 2003-321299 A.

Although the filamentary crystals of iron oxide and titanium oxide possess many useful properties which have been the subject of numerical applications, the desired structural arrangement and shapes of the whiskers for the applications have no been obtained. Therefore, it is an object of this invention to provide the small filamentary crystals of iron oxide and titanium oxide in the form of whisker with a high aspect ratio and to provide the structures having the whiskers densely erected thereon, which are useful as catalyst in the flowing gas or fluid, etc. and the process for producing said whiskers and structures.

### BRIEF SUMMARY OF THE INVENTION

In accordance with the present invention, the preferred whiskers are densely and uniformly erected on a substrate and thin iron oxide whiskers of high aspect ratio and thin titanium oxide whiskers of high aspect ratio.

Further, the present invention provides the structure having iron oxide whiskers of high aspect ratios densely erected hereon. In the production of said structure, an iron based alloy is brought into contact with an oxidative atmosphere so as to react the surface iron atoms with oxygen brought into contact therewith at high temperature, thereby attaining growth as oxide whiskers.

Further, the present invention provides the structure having titanium oxide whiskers of high aspect ratios densely erected hereon. In the production of said structure, an titanium based alloy is brought into contact with an oxidative atmosphere so as to react the surface iron atoms with an oxygen brought into contact therewith at high temperature, thereby attaining growth as oxide whiskers.

Further, this invention provides an iron oxide whisker of 5 nm to 2 μm diameter and an aspect ratio higher than 20, wherein the content of non-iron metal atoms is less than 10 percent atomic volume. In the production of the iron oxide whiskers, an iron based alloy is brought into contact with an oxidative atmosphere so as to react the surface iron atoms with oxygen brought into contact therewith at high temperature, thereby attaining growth as oxide whisker.

Further, this invention provides an titanium oxide whisker of 5 nm to 2 μm diameter and an aspect ratio higher than 5. In the production of the titanium oxide whiskers, an titanium based alloy is brought into contact with an oxidative atmosphere so as to react the surface titanium atoms with oxygen brought into contact therewith at high temperature, thereby attaining growth as oxide whiskers.

This invention further provides a method for producing said oxide whiskers. In the production of the oxide whiskers, an titanium or iron based alloy is brought into contact with an oxidative atmosphere so as to react the surface titanium or iron atoms with oxygen brought into contact therewith at high temperature, thereby attaining growth as oxide whiskers.

Further, in the production of the oxide whiskers, the metal alloy is heated with a temperature gradient along the thickness direction of said metal alloy for the purpose of hastening the whisker growth and brought into contact with an oxidative atmosphere so as to react the surface metal atoms with oxygen brought into contact therewith at high temperature, thereby attaining growth as oxide whiskers.

The iron oxide whiskers in the present invention are the thin whiskers of high aspect ratio and prepared without dendrite by controlling the production parameters. They have superior magnetic property and can provide high density magnetic recording media.

Further, the structures having said oxide whiskers erected exert excellent characteristics, such as large contact area as a catalyst, freedom from clogging and reusable for carbon dioxide decomposition, and hence highly useful

The titanium oxide whiskers in the present invention are the thin whiskers of high aspect ratio and have large contact areas as photo-catalyst

Further, the structures having said oxide whiskers erected hereon exert excellent characteristics, such as large contact area as a catalyst, freedom from clogging and reusable, and hence highly useful.

### DESCRIPTION OF THE DRAWINGS

FIG. 1 is a scanning electron photomicrograph of the tip of wustite whisker of 5 nm diameter and length 230 nm.

FIG. 2 is a scanning electron photomicrograph at the base of whiskers of the magnetite and hematite poly crystalline mixture. The diameters of the whiskers are between 100 nm and 3 μm. The longest whisker is 1 cm and the thickness 1 μm. In the background of the microphotograph are aggregates of magnetite polycrystalline on the surface of the iron based substrate plate.

FIG. 3 is a scanning electron photomicrograph of the tip of magnetite whisker (the thickness is 750 nm). The cyclic change in thickness is apparent.

FIG. 4 is a cross-sectional view of the apparatus for growing oxide whiskers on the surface of a metal substrate plate heated by flame.

FIG. 5 is a cross-sectional view of the apparatus for growing oxide whiskers on the surface of a metal substrate plate placed in the quartz tube.

FIG. 6 is a graph for vapor pressure v.s. temperature for various oxides.

FIG. 7 is a sketch depicting a potential growing process of an iron oxide whisker.

FIG. 8 is a scanning electron photomicrograph of titanium oxide whiskers grown on an titanium based metal plate substrate.

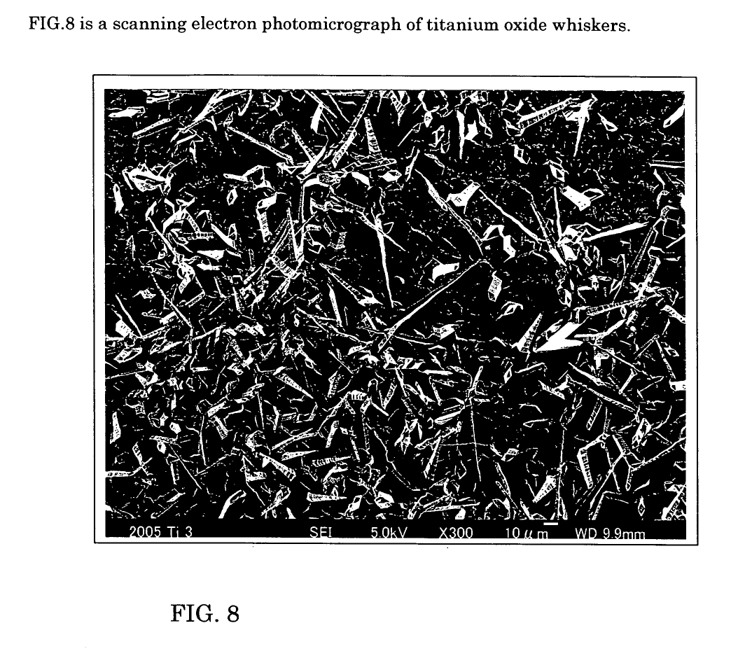

FIG. 9 is a scanning electron photomicrograph of iron oxide whiskers grown on an iron based metal plate substrate.

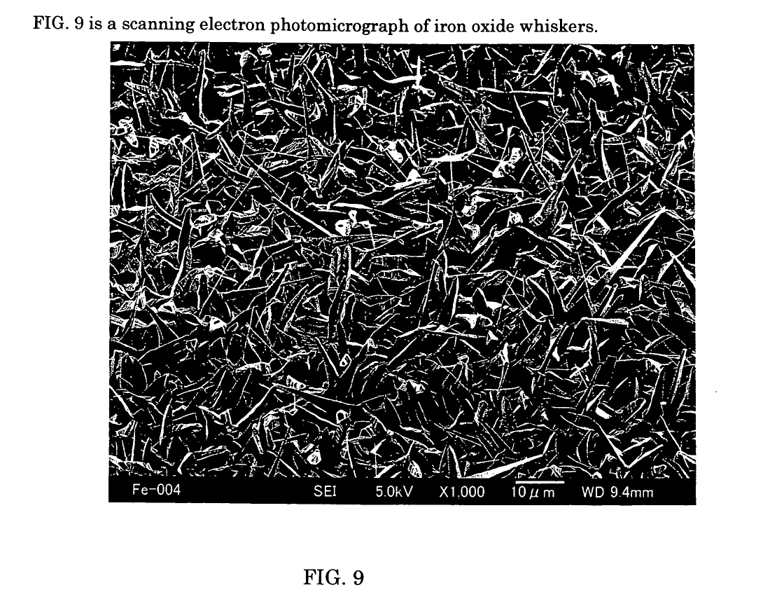

FIG. 10 is a scanning electron photomicrograph of spiral whiskers, A and zigzag whiskers, B.

FIG. 11 is scanning electron photomicrographs of (A) the hallow magnetite whisker milled by FIB and (B) the magnetite whiskers grown from a magnetite agglomerate.

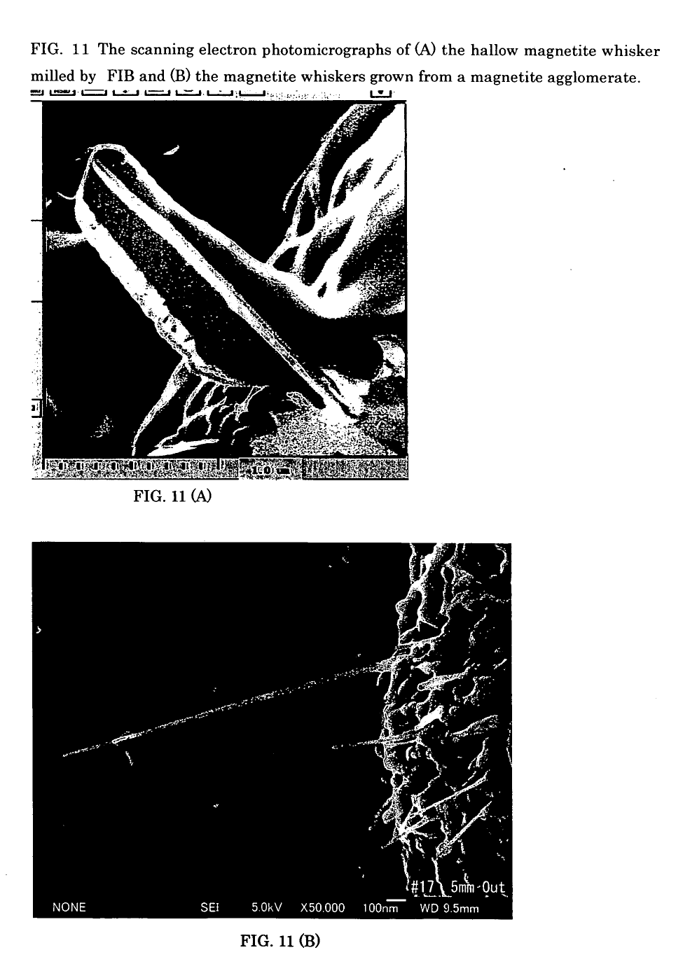

### DESCRIPTION OF THE NUMERALS

10: the substrate plate; 11: the whisker growing surface; 12: the substrate surface to be heated; 13: the cover plate; 14: the hole of the cover plate; 15: the supporting frame; 16: the disk; 17: the tapered hole; 18: the flame; 19: the burner; 20: the substrate; 21: the substrate holder; 22: the quartz tube; 23: the infrared electric furnace; 24: the gas inlet; 25: the gas outlet.

### DETAILED DESCRIPTION OF THE INVENTION

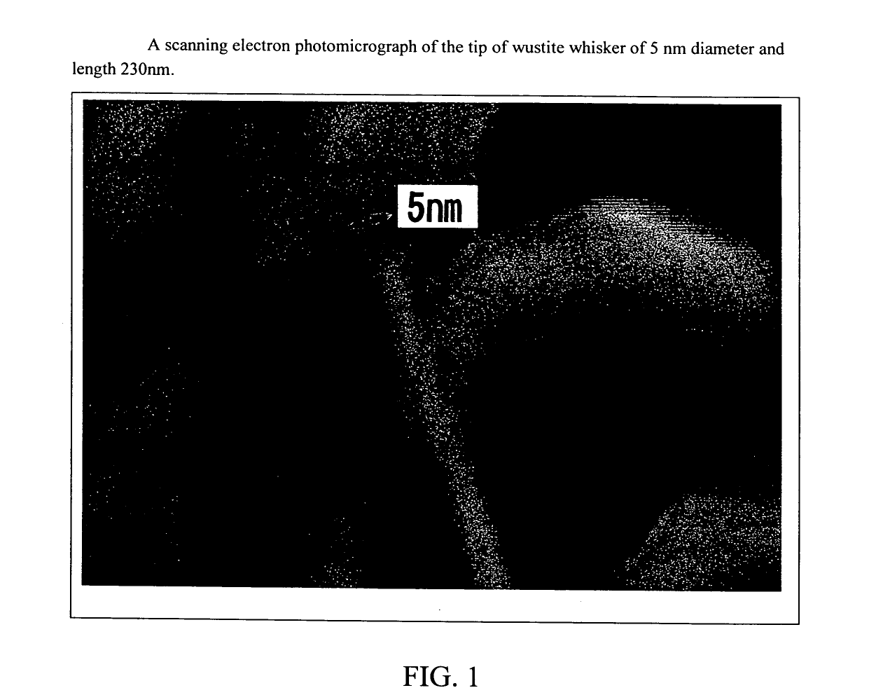

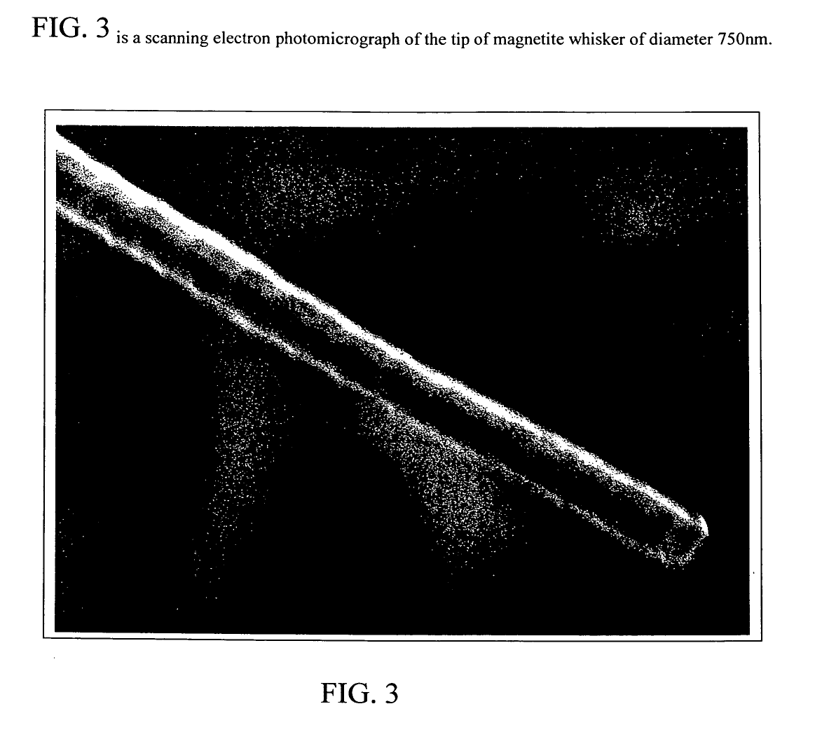

The more details for iron oxide whiskers are described. In the present invention, the iron oxide whiskers of lengths between 5 nm and 20 μm or of any length such as 10 m or 100 m, which is limited by the process time and the production facility are produced. In practice, because the longer whiskers are chopped to whiskers of aspect ratios about 100 or so and used as catalyst or magnetic recording media, the preferred lengths of whiskers are lengths between 1 μm and 100 μm. The whisker length is decided by measuring the length of the whisker in the photomicrograph as shown in FIG. 3 and multiplying a proper magnification factor. The diameter of a whisker is decided by measuring the diameter of the whisker in a photomicrograph as shown in FIG. 1 or FIG. 3 and multiplying a proper magnification factor. When the cross section shape of a whisker is a polygon, the diameter in the present invention means the diameter of the smallest circle including this polygon.

The control aspect ratios for whiskers are more easily obtained by controlling process parameters such as oxygen containing gas pressure, temperature or growth time than by cutting longer whiskers shorter.

The iron oxide whiskers in the present invention are the whiskers of wustite (FeO between, Fe_{0.98}O, Fe_{0.94}O), hematite(Fe₂O₃), maghemite (Fe₂O₃, γ-Fe₂O₃), magnetite (Fe₃O₄), cation excess magnetite (Fe_{3+δ}O₄) cation deficient magnetite (Fe_{3-δ}O₄), any binary compound of iron and oxygen atoms; FeₓO_{y}, with x being between 1 and 3, and y, between 1 and 4, and any mixture of binary compounds of iron and oxygen atoms, wherein the content of non-iron metal atoms is less than 10 atom %, preferably less than 8 atom % or more preferably 0.5 atom %. The whiskers containing non-iron metal atoms greater than 10 atom % tend to be much weaker than that of theoretical strength due to structural defects associated with the foreign atoms in the whisker crystal.

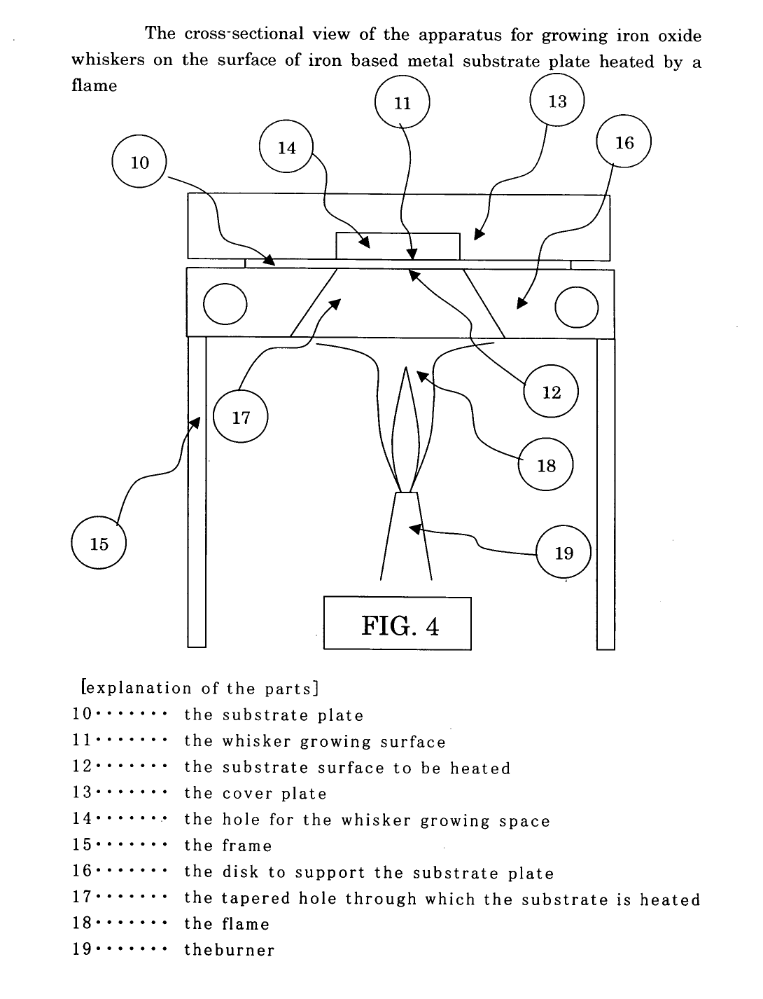

A whisker grown on the 1 mm thick SUS304 plate by the apparatus depicted in FIG. 4., was analyzed by the transmission electron microscopy (TEM) with energy dispersive X-ray (XDA) analyzer with the estimation limit of 0.5 atom % for chromium, zinc, cobalt, niobium, nickel, manganese, cupper, etc., and no atom other than oxygen and iron atoms was detected.

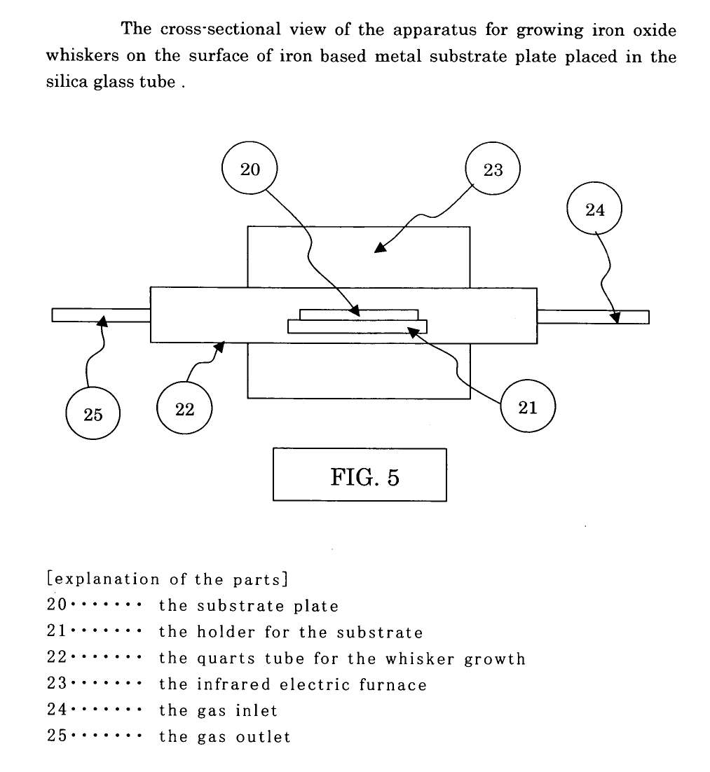

Due to the balance between the cohesion energy of the iron and oxygen whisker crystal and the surface energy of the whisker crystal, the minimum value of the whisker thickness is estimated about 5 nm. The preferred length for the whisker thickness is decided as 2 μm because the effectiveness of iron oxide whiskers in magnetic storage device or as catalyst diminishes for the thickness greater than 2 μm. Also, the iron oxide whiskers are erected on the surface of the iron based alloy heated in the oxygen containing atmosphere by the apparatus depicted in FIG. 5

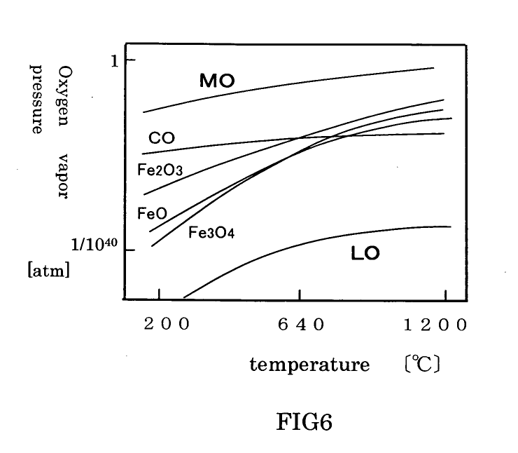

The growth of a whisker on the surface of iron based alloy may consists of two steps. The first step is the oxidation of the alloy surface and the second, the whisker growth from the alloy surface. The oxidation step is associated with the oxygen vapor pressure of metal oxide. In FIG. 6. the oxygen vapor pressures for various oxides are depicted. The oxygen atoms less tend to form the metal oxides with the metal atoms in the iron based alloy, depicted by MO curve which includes the oxides of cobalt, nickel, copper and palladium than the metal oxides such as Fe O, Fe₃O₄ and Fe₂ O₃. On the other hand, the oxygen atoms tends to form the oxides corresponding to the curve LO which includes the oxides of titanium, chromium and niobium before forming the iron oxides. Thus, the iron based alloy containing these atoms are less preferable for the iron whisker growth.

A whisker is formed as a thin and long crystal when one crystal face grows extremely faster than the other crystal surfaces with a certain mechanism. Three mechanisms have been explained for the whisker growth. The one crystal plane grows much faster than the other crystal planes, resulting in a whisker like crystal, which in many cases associated with the existence of screw dislocation in the plane. The second mechanism is the Vapor-Liquid-Solid (VLS) mechanism in which a whisker grows with a droplet of supersaturated alloy solution at the tip of the whisker. The third mechanism is the growth from the base of crystal where the atoms constituting the whisker crystal are supplied. The main mechanism for the formation of an iron oxide whisker is thought the third mechanism with other mechanisms partially involved As the whisker grows out the substrate plate, it is exposed to different high temperatures and oxidative atmospheres and, then, the growth mechanism may change from that at the whisker base. Further, as shown in FIG. 3, some whiskers thicker than 500 nm grow with thickness variations like bamboo joints. This type of thickness variation is observed in whiskers grown in the VLS mechanism, which is not yet clearly explained in the well defined VLS mechanism. As described, the growth mechanism in the present invention is not fully explained yet.

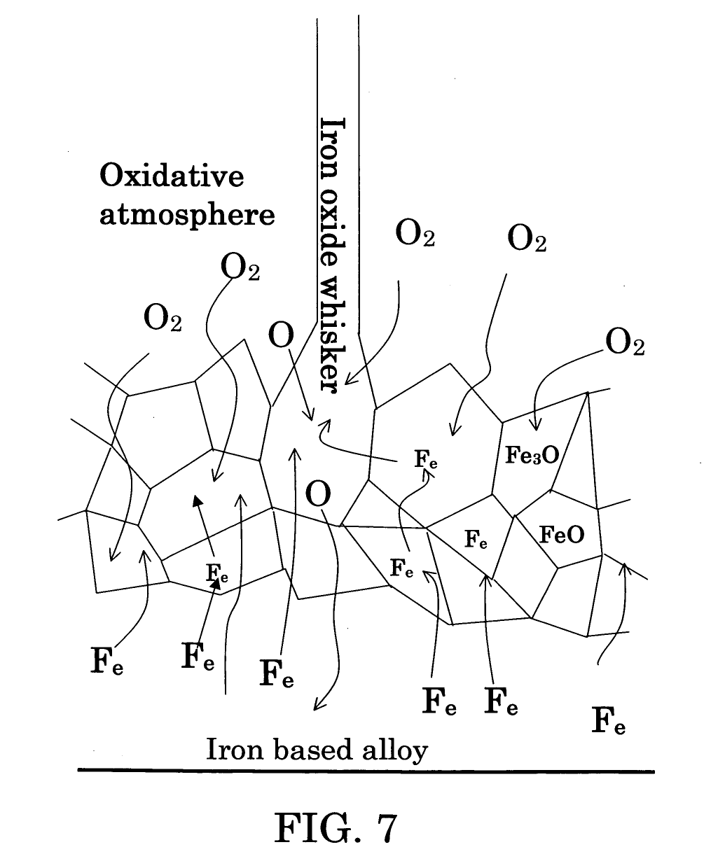

During the whisker growth, the diffusion speed of iron atom to the surface and the supply speed of oxygen from the surface related to the oxygen vapor pressure governs the whisker growth speed and the thickness of the growing whisker, coupled with the energy balance of the creation of new whisker surface and the cohesive energy of the iron oxides consisting of the whisker. Also, governing the whisker growth are the temperatures and temperature gradients in the iron based alloy, as well as the densities and density gradients of, oxygen atoms, iron atoms and various oxides in the base alloy and the whisker. In FIG. 7, the possible whisker growth mechanism is depicted for a temperature about 700° C. Iron atoms defuse toward the surface from the inside of the alloy and oxygen atoms in the atmosphere defuse into the alloy, forming iron oxides such as FeO, Fe₃O₄ and Fe₂O₃ Out of these iron oxides, magnetite crystal more likely grow out as whiskers.

When the one surface of the iron based alloy plate is heated and the other surface, with the temperature kept lower than that of the heated surface, is exposed to the oxygen containing gas, as depicted in FIG. 4, iron oxide whiskers grow on the surface contacting with the gas with a higher growth speed. In this case, the iron atoms diffuse toward the whisker growing surface more faster because the lower solubility of solute atoms at a lower temperature cause the iron atoms to diffuse to that direction, resulting in the faster iron oxide whisker growth speed. In the present invention, one or more of substitution or interstitial solute atoms contained in the iron based alloy, which are associated with the diffusion of the iron atoms toward the whisker growing side, are Hydrogen, Carbon, Nitrogen, Oxygen, Boron, Calcium, Nickel, Chromium, Silicon, Aluminum, Sulfur, Phosphorus, Vanadium, Titanium, Niobium, Molybdenum, Tungsten, Manganese, Copper, Cobalt, Tantalum, Selenium. The atoms do not dissolve in an iron alloy solution are not included because they are not related to the iron atom diffusion to the whisker growing surface. For the diffusion of solute atoms, the temperature gradient in a substrate plate is more effective. When providing a temperature gradient in the substrate plate, the temperature of the substrate surface to be heated can be higher than the alloy melting temperature, but the temperature of the substrate plate surface erecting whiskers hereon must be lower than the melting temperature. The process for preparing whiskers with a temperature gradient in the substrate plate is effective not only for the titanium whisker growth but also for many other metal oxide whiskers including the titanium oxide whiskers.

In the present invention, the preferred iron based alloys are; (1) pure iron, which is 100% pure iron at the atomic level or pure iron metal with impurities inevitably left in the metallurgical process. (2) iron based alloys containing iron atoms between 10 weight % and 99.999 weight %, and the balance, one or more of atoms between atomic number 3 (Lithium) and 103(Lawrencium) except the inert gasses, (3) alloys containing iron atoms between 0.001 weight % and 10 weight %, and the balance, atoms whose oxide has the oxygen vapor pressure higher than that of hematite (Fe₂O₃) at temperatures between 50° C. and 1500° C. The atoms are one or more of Cobalt, Nickel, Copper and etc. and (4) the materials made from said iron based alloys of (1), (2) and (3), such as layer, clad, mixtures coprecipitant and etc.

The whiskers grown on said alloys of (1),(2),(3) and (4) may contain metal atoms diffused into the whiskers from the alloy, wherein the content of said atoms is no more than 10 atom %. The preferred form of alloy can be any form of solid, such as rod, foil, plate, tube, machined or welded. The alloy is subjected to temperatures sufficiently high to cause oxygen diffuse into the alloy from the contacting oxygen containing gas to form the whiskers on the surface. These temperatures of the surface where whiskers grow are preferably between 50° C. and 1500° C. or more preferably between 600° C. and 1500° C. When the one side of alloy plate is heated and the other side is subjected to the oxygen containing gas, the temperature of the surface heated are preferably between 100° C. and 2000° C., which are higher than that of the whisker growing surface.

In the said temperature range, the atmospheric air or the air with controlled moisture and temperature is used as an oxygen containing gas. Further, pure oxygen gas or a gas containing oxygen of a volume percent between 0.001 vol % and 100 vol % with one ore more of the following gases can be use; hydrogen, helium, nitrogen, fluorine, neon, chlorine, argon, bromine, krypton, iodine, ammonia, xenon, radon, carbon dioxide, carbon monoxide, nitric oxide, nitrogen dioxide, dinitrogen oxide, hydrogen sulfide hydrogen fluoride, methane, ethane, propane, acetylene, alcohols including primary, secondary, and tertiary alcohols, hydrogen sulfide, frons, ozone. etc.

Highly oxidative gases such as chlorine gas, fluorine gas hydrogen fluoride can be used to etch the metal atoms out at the growing whisker surface, thus controlling the whisker thickness. Since it is extremely difficult to understand the precise conditions surrounding individual whisker when it is growing and to control the conditions, the growth condition is determine by a trial and error method for changing the whisker production parameters.

The more details for a titanium oxide whisker are described. The preferred titanium oxide whiskers have lengths between 5 nm and 20 μm and any length such as 10 m and 100 m which is limited by the process time and the production facility. In practice, because the longer whiskers are chopped and used as whiskers of aspect ratios of about 100 or so, the preferred length of whiskers are lengths between 1 μm and 100 μm.

The length and diameter of a titanium oxide whisker is decided by the same method as that for an iron oxide whisker. The control aspect ratios for whiskers are more easily obtained by controlling process parameters such as oxygen containing gas pressure, temperature or growth time.

In the present invention, titanium oxides mean one or more of TiO, TiO₂, Ti₂O, Ti₂O₃, Ti₂O₅, Ti₃O, Ti₃O₅, Ti₃O₇. The titanium oxide whisker contains non-titanium metal atoms less than 10 atom %, preferably less than 8 atom %, or more preferably 0.5 atom %. A titanium oxide whisker containing non-titanium metal atoms more than 10 atom % tends to loose strength significantly.

The titanium oxide whisker looses strength exponentially as the whisker decreases beyond certain value of the diameter. This limiting value determines the smallest diameter of the whisker, which is estimated as 5 nm by the balance between the cohesion energy of titanium and oxygen whisker crystal and the surface energy of the whisker crystal. The largest value for the diameter is decided as 20 μm by the effective surface area per unit volume as a catalyst. Since the thicker the whisker is, the smaller the whisker surface area per unit volume is.

Titanium oxide whiskers in the present invention grow by the similar manner as that of iron oxide whiskers. As shown in FIG. 4. or FIG. 5, the titanium containing alloy including pure titanium is brought into contact with an oxidative atmosphere so as to react the surface titanium atoms with oxygen brought into contact herewith at high temperature, thereby attaining growth as oxide whiskers. Further, with a temperature gradient in the titanium alloy as shown in FIG. 4, the expedited titanium oxide whisker growth can be attained on the surface of lower temperature.

Said whisker is formed as a thin and long crystal when one crystal face grows extremely faster than the other crystal surfaces with a certain mechanism. The one crystal plane with an edge dislocation can grow spirally much faster than the crystal plane without edge dislocations. Other whisker growth mechanism is the VLS growth which involves the supersaturation of solid solution at the tip of the whisker. The third mechanism is the growth from the base of the whisker crystal where atoms constituting the whisker crystal are supplied at the base. The main mechanism for the formation of titanium oxide whisker in the present invention is thought the third mechanism with other mechanisms partially involved. As the whisker grows out the substrate plate, it is exposed to different high temperatures and oxidative atmospheres, the growth mechanism may change from that at the whisker base, which can not be clearly explained presently. In the similar manner to the iron oxide whisker growth in the present invention, the titanium oxide whisker growth in the present invention can not be fully explained and the best oxidative atmosphere must be selected for each type of titanium alloy and oxygen containing gas by a trial and error.

In the present invention, the preferred titanium based alloys are the followings.

(5) pure titanium, which is 100 % pure titanium at the atomic level or pure titanium metal with impurities inevitably left in the metallurgical process.

(6) titanium based alloys containing titanium atoms between 10 weight % and 99.999 weight %, and the balance, one or more of atoms between atomic number 3 (lithium) and 103(lawrencium) except the inert gasses.

(7) titanium alloys containing titanium atoms between 0.001 weight % and 10 weight %, and the balance, atoms whose oxides have the oxygen vapor pressure higher than that of TiO at temperatures between 50° C. and 580° C. The atoms are one or more of Sn, V, Co, Mn, Ni, Fe, Si, Cu and on the other hand, are not P and Ca.

(8) the constructions from said titanium based alloys of (5), (6) and (7) such as layer, clad, mixture, co-precipitant and etc.

In the case that said titanium based alloy are used as substrates for the titanium oxide whisker growth, non-titanium metal atoms may diffuse into the whisker, whereon the content of such atoms is less than 10 atom %. The preferred form of titanium based alloy can be any form of alloy that is solid such as rod, foil, plate, tube, machined or welded.

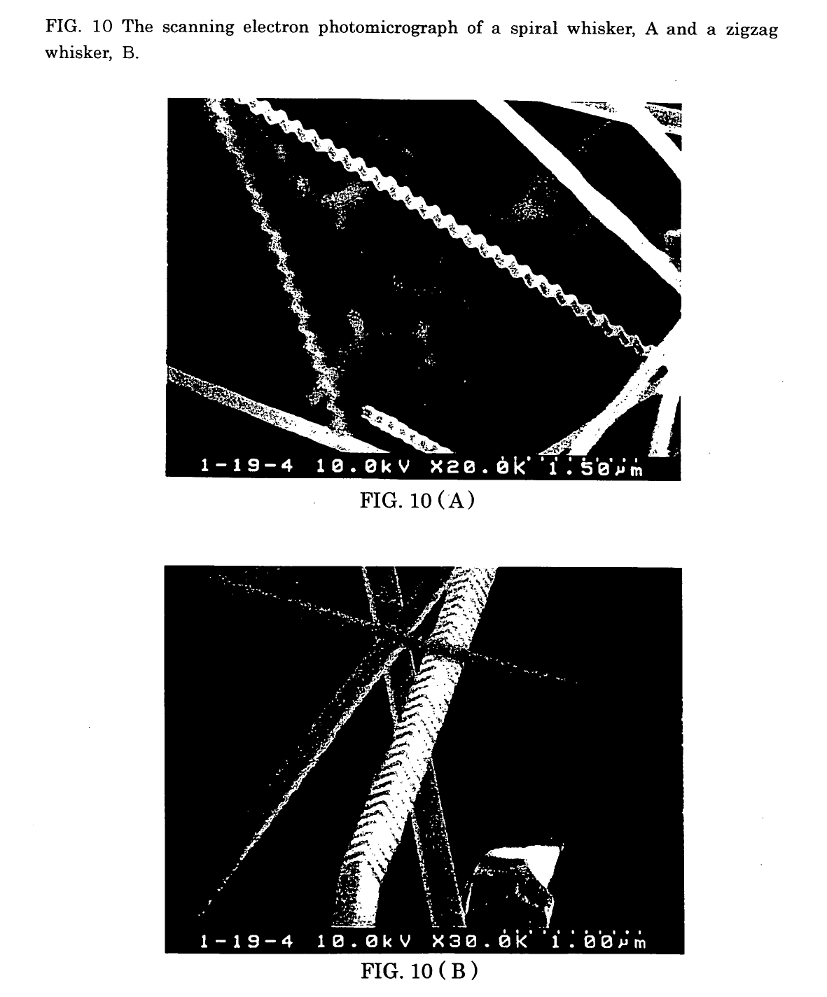

In the case that the whiskers grow from the oxide crystals formed on the alloy surface, these crystals strongly adhere each other and form one large polycrystalline substrate with the whiskers firmly attached hereon. The whiskers thus grown reflect the crystal direction of the base oxide crystal directions. The whisker can grow epitaxially without any crystal defects or with dislocations or kinks, which is shown in FIG. 10.

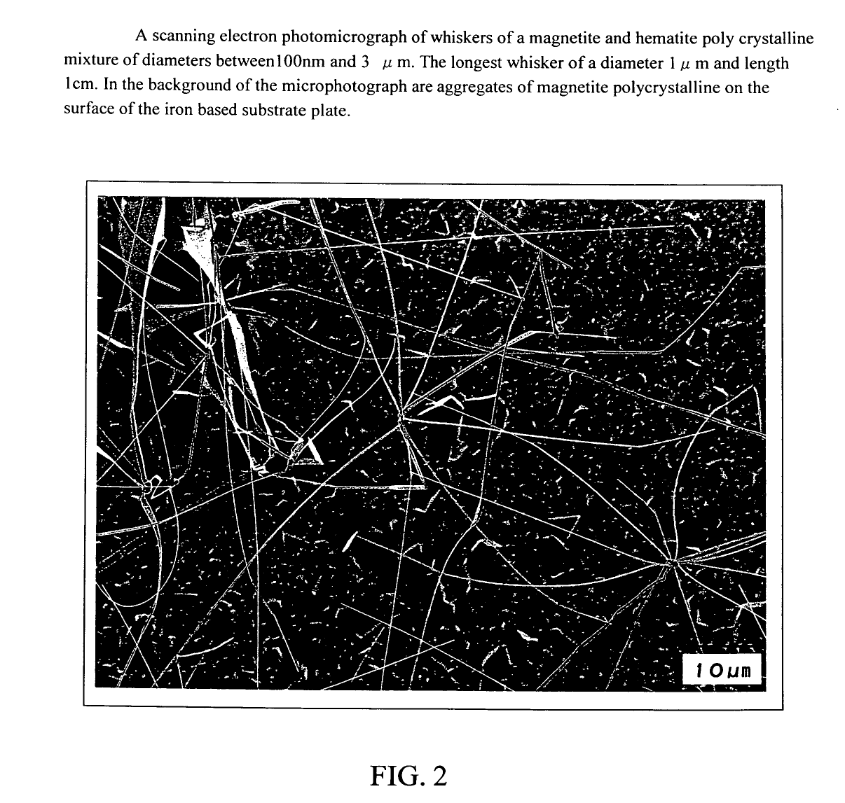

The whiskers in the present invention are tightly attached to the substrate plate and, when used as catalysts in a flowing gas and subjected to bending load by the flowing gas, are not easily broken away from the substrate, preventing the gas passage way from being clogged. The direction of the whisker growth can be controlled by the direction of the iron or titanium oxide crystal grown on the surface, which can be also controlled by controlling the crystal direction of the alloy at the surface by etching or by plastic deformation. The whisker density can be increased by decreasing the size of oxide crystals grown on the surface from which the whiskers grow, or by letting the whiskers branching out more from one point as shown in FIG. 2 with a properly selection of the process parameters such as temperature, oxygen contents and process time. Further, by introducing more dislocations on the alloy surface by plastic deformation from which the oxide crystal growth initiates, the dense oxide growth can be achieved.

In the present invention, the iron or titanium based alloy can be any size and shape such as plate, foil and bar, machined, welded, cast or forged. Said alloy can be the honeycomb shape or tube on whose inner or outer surface the whiskers can grow.

The iron oxide whiskers in the present invention are the thin whiskers of high aspect ratio and are grown without dendrite by controlling the production parameters. They have superior magnetic property and can provide high density magnetic recording media.

Further, the structures having said oxide whiskers erected exert excellent characteristics, such as large contact area as a catalyst, freedom from clogging and reusable for carbon dioxide decomposition, and hence highly useful

The titanium oxide whiskers in the present invention are the thin whiskers of high aspect ratio and have large contact areas as photo-catalyst

The nature and objects of the invention are illustrated by the following examples, which are provided for only illustrative purpose and not to limit the invention as define by the claims.

Referring to FIG. 4, the method of producing whiskers on the substrate surface of metal based alloy is illustrated. The substrate plate,10, is placed on the plate 16, fixed on the frame 15. The plate surface 12, is heated by the flame 18, through the tapered circular hole 17, of the plate 16, where the fuel gas and oxygen gas is connected to the torch 19, which are not depicted in FIG. 4, and the flow rates of these gases are regulated, where a regulator is neither depicted in FIG. 4. While measuring by thermocouple the temperature of the surface of the substrate plate which is not heated and regulating the fuel and oxygen gas flow rate, the desired surface temperatures is set. Then, the cover plate 13, is placed over the substrate plate 10, to keep the temperature of the substrate surface constant and the hole 14 of the cover plate is properly adjusted to protect the whisker growing surface 11. The diameter and depth of the hole, 14, of the cover plate is properly designed so that it contains enough oxygen and has enough space for the growth of the oxide whiskers. Finally, the flame is kept the same for a certain duration of time for the whisker growth. The hole 14, of the cover plate is connected to the regulator through which the oxygen containing gas and argon gas flows are regulated. The heating of the substrate plate can be done by contacting the surface with a high temperature media such as gas, plate, or wire. In FIG. 4, though the substrate plate is placed between two circular holes of the plate, any shape for the plates and holes can be used, dependent on the substrate shape.

### EXAMPLE 1

The SUS304 plate of 0.1 mm thickness as the substrate 10, was heated through the tapered hole 17, by the flame 18, of a propane and oxygen gasses mixture for 15 minutes. The diameters of the hole 14, and tapered hole 17, were 20 mm. On the surface 11, of substrate plate 10, near the center of the hole 14, the iron oxide whiskers of a thickness between 200 nm and 1.7 μm and a length up to 200 μm grew and at 7 mm from the center, the iron oxide whiskers of a thickness between 50 nm and 100 nm and a length up to 2 μm grew. When the SUS304 plate of the same dimension was heated with the same conditions except the cover plate,13, removed, the temperatures of the substrate where whiskers grew were between 450° C. and 900° C.

### EXAMPLE 2

In the similar manner to Example 2, the 0.1 mm thick titanium plate, instead of the SUS304 plate, was for 20 minutes. On the surface, 11, of the substrate plate near the center of the hole, 14, the titanium oxide whiskers of a thickness between 200 nm and 10 μm and a length up to 0.4 mm grew and at 7 mm from the center, the titanium oxide whiskers of a thickness between 10 nm and 100 nm and a length up to 400 nm grew. When the titanium plate of the same dimension was heated with the same conditions except the cover plate, 13, removed, the temperatures of the substrate where whiskers grew were between 450° C. and 850° C., which are understood as the whisker growing temperatures.

Referring to FIG. 5, the method of producing whiskers on the substrate surfaces of metal based alloy in the quartz tube is illustrated. The substrate plate, 20, is set on the substrate holder, 21, and the holder is placed in the quartz tube, 22. The quartz tube is placed in the infrared electric furnace, 23. The oxygen containing gas is supplied through the gas inlet, 24 and at the same time exhausted through the gas outlet, 25 till the gas pressure reaches a proper pressure for the whisker growth. Those connected to the gas inlet line, 24, which are not shown in FIG. 5, are the oxygen containing gas, the inert gas, a mass flow meter and flow control valves, thermocouples to measure the substrate plate temperature, 20, a pressure gage to measure the gas pressure in the quartz tube, 22. Further, those connected to the gas outlet lines 25, which are not shown in FIG. 5 are a vacuum pump, a relief valve and flow control valves. After the gas pressure reaches the whisker growing pressure, the quartz tube, 22 is heated to the proper temperature kept at that temperature for a certain predetermined duration of time. In the present invention, the oxygen containing gas can be supplied after the substrate temperature reaches the whisker growing temperature or the gas can be stopped after the gas reaches the whisker growing pressure. The combination of the partial pressure of oxygen gas or oxygen containing gas, the substrate temperature and the growth time determines the whisker density on the substrate surface, the whisker length and thickness and whisker morphology.

### EXAMPLE 3

The substrate plate 20, of pure iron of 30 mm×30 mm and 1 mm thick was set on the substrate holder, 21, the holder was placed in the quartz tube 22, and the quartz tube was placed in the infrared electric furnace 23. Then, the mixture of argon gas and oxygen gas of 20,000 Pa partial pressure was supplied, heated to 650° C. in 5 min and kept at 650° C. for one hour and the tube was cooled in air. On the both surfaces of the plate, the whiskers with length up to 2 μm and thickness less than 100 nm were observed densely grown, protruding from the surfaces. The oxygen gas partial pressure was close to 0.1 Pa. when the tube was cooled down to the room temperature. It was thought that the whisker grew at the oxygen gas partial pressure between 20,000 Pa and 0.1 Pa

### EXAMPLE 4

The substrate plate 20, of pure titanium plate of 30 mm×30 mm and 1 mm thick was set on the substrate holder, 21, the holder was placed in the quartz tube, 22, and the quartz tube was placed in the infrared electric furnace 23. Then, the mixture of argon gas and oxygen gas of 20,000 Pa partial pressure was supplied, heated to 750° C. in 5 min and kept at 750° C. for two hours and the tube was cooled in air. On the both surfaces of the plate, the titanium whiskers with thicknesses less than 50 nm and lengths up to 1 μm were observed densely grown, protruding from the surfaces. The oxygen gas partial pressure was close to 0.1 Pa. when the tube was cooled down to the room temperature. It was thought that the whisker grew at the oxygen gas partial pressure between 20,000 Pa and 0.1 Pa

### EXAMPLE 5

In the same procedure as that of EXAMPLE 1, the apparatus depicted in FIG. 4 was used. The thickness of SUS304 plate was 1 mm, the highest temperature measured on the whisker growing surface was 700° C. The flame was kept steady for two hours with the SUS 304 plate covered with the cover plate, 13. Within the 10 mm diameter circle from the center of the flame on the whisker growing surface 11, the magnetite whiskers of length between 100 nm and 1 cm and thickness between 50 nm and 300 nm grew with the density of one whisker per the square area of 10 μm by 10 μm.

### EXAMPLE 6

In the same procedure as that of EXAMPLE 5, the apparatus depicted in FIG. 4 was used. The thickness of SUS304 plate was 2 mm, the highest temperature measured on the whisker growing surface was 700° C. The flame was kept steady for one hour with the SUS 304 plate covered with the cover plate, 13. Within the 10 mm diameter circle from the center of the flame on the whisker growing surface, 11, the whiskers are the mixture of magnetite and hematite crystals. And the longest whisker was 8.5 mm and the thickest, 1.9 μm.

### EXAMPLE 7

In the same procedure as that of EXAMPLE 1 except that the substrate plate was 0.1 mm thick SWRS92A iron alloy and the atmosphere gas was the mixture of oxygen gas of 10 vol %, nitrogen gas of 88 vol % and chlorine gas of 2 vol %. Within the 8 mm diameter circle from the center of the flame on the whisker growing surface, the wustite whiskers were erected with the density of 8 whiskers per 10 μm by 10 μm area The longest whisker was 280 nm with the thickess, 5 nm.

### EXAMPLE 8

In the same procedure as that of EXAMPLE 1, the apparatus depicted in FIG. 4 was used. The thickness of pure titanium plate was 2 mm, the highest temperature measured on the whisker growing surface was 710° C. The flame was kept steady for one hour. The longest whisker was 1 mm with the thickness of 16 μm.

### EXAMPLE 9

In the apparatus depicted in FIG. 5, the substrate was a pure iron plate of 30 mm×30 mm and 1 mm thick The mixture of argon and oxygen gases was being supplied with 15 CCM and the gas pressure was kept 500 Pa with the oxygen partial pressure of 150 Pa. The temperature was raised to 700° C. in 5 min and kept at 700° C. for 30 minutes. Then the gas flow was stopped and cooled down to the room temperature. The magnetite whiskers were densely erected on the surface almost perpendicular to the surface. The thicknesses of whiskers were those up to 100 nm and lengths, those up to 1 μm.

### EXAMPLE 10

In the apparatus depicted in FIG. 5, the substrate was a pure titanium plate of 30 mm×30 mm and 1 mm thick and used with the same whisker growth conditions as example 6. The titanium dioxide whiskers were densely erected on the surface almost perpendicular to the surface. The thicknesses of whiskers were those up to 100 nm and the longest, 500 nm.

### EXAMPLE 11

In the apparatus depicted in FIG. 5, the substrates were the 1 mm diameter and 10 cm long wires of SS40 steel, invar, SUS304 and pure iron. The mixture of argon and oxygen gases was being supplied with 15 CCM and the gas pressure was kept 500 Pa with the oxygen partial pressure of 150 Pa. The temperature was raised to 750° C. in 5 min and kept at 750° C. for 30 minutes. Then the gas flow was stopped and cooled down to the room temperature. The magnetite whiskers were densely erected on the surface almost perpendicular to the surface. The thicknesses of whiskers were those up to 100 nm and the lengths, those between 200 nm and 1 μm.

The iron oxide whiskers in the present invention are the thin whiskers of high aspect ratio and are grown without dendrite by controlling the production parameters. They have superior magnetic property and can provide high density magnetic recording media. Further, the structures having said oxide whiskers erected exert excellent characteristics, such as large contact area as a catalyst, freedom from clogging and reusable for carbon dioxide decomposition, and hence highly useful. The titanium oxide whiskers in the present invention are the thin whiskers of high aspect ratio and have large contact areas as photo-catalyst. Further, the structures having said oxide whiskers erected hereon exert excellent characteristics, such as large contact area as a catalyst, freedom from clogging and reusable, and hence highly useful.

We claim:

1. An iron based alloy having a surface or surfaces on which iron oxide whiskers of high aspect ratio are erected.

2. An iron based alloy having a surface or surfaces on which iron oxide whiskers of high aspect ratio are erected as claimed in claim 1. In the production of said iron oxide whiskers, a said iron based alloy is brought into contact with oxidative atmosphere so as to react the surface iron atoms with oxygen atoms brought into contact therewith at high temperature, thereby attaining growth as oxide whiskers.

3. A titanium based alloy having a surface or surfaces on which titanium oxide whiskers of high aspect ratio are erected.

4. A titanium based alloy having a surface or surfaces on which titanium oxide whiskers of high aspect ratio are erected as claimed in claim 3. In the production of said titanium oxide whiskers, a said titanium based alloy is brought into contact with oxidative atmosphere so as to react the surface titanium atoms with oxygen atoms brought into contact therewith at high temperature, thereby attaining growth as oxide whiskers.

5. An iron oxide whisker of 5 nm to 2 μm diameter and of an aspect ratio higher than 20, wherein the content of non iron metal atoms is less than 10 percent atomic volume.

6. An iron oxide whisker as claimed in claim 5, In the production of said iron oxide whiskers, a said iron based alloy is brought into contact with oxidative atmosphere so as to react the surface iron atoms with oxygen atoms brought into contact therewith at high temperature, thereby attaining growth as oxide whiskers.

7. A titanium oxide whisker of 5 nm to 2 μm diameter and of an aspect ratio higher than 5, where in the content of non iron metal atoms is less than 10 percent atomic volume.

8. A titanium oxide whisker as claimed in claim 7. In the production of said titanium oxide whiskers, a said titanium based alloy is brought into contact with oxidative atmosphere so as to react the surface titanium atoms with oxygen atoms brought into contact therewith at high temperature, thereby attaining growth as oxide whiskers.

9. A method of erecting oxide whiskers of a high aspect ratio on a surface or surfaces of an iron or titanium based alloy, which comprises bringing an said iron or titanium based alloy into contact with oxidative atmosphere so as to react the surface iron atoms or the surface titanium atoms with oxygen atoms brought into contact therewith at high temperature, thereby attaining growth as oxide whiskers.

10. A method of erecting oxide whiskers of a high aspect ratio on a surface or surfaces of an iron or titanium based alloy, which comprises bringing an said iron or titanium based alloy into contact with oxidative atmosphere so as to react the surface iron atoms or the surface titanium atoms with oxygen atoms brought into contact therewith at high temperature, thereby attaining growth as oxide whiskers as claimed in claim 9, wherein the growth of said oxide whiskers is hastened by a temperature gradient provided in an said iron or titanium based alloy.
